(19) United States
(12) Patent Application Publication
(10) Pub. No.: US 2018/0029477 A1
(43) Pub. Date: Feb. 1, 2018

(54) SOLAR POWERED DRONE

(71) Applicant: Simon Gojcaj, Macomb, MI (US)

(72) Inventor: Simon Gojcaj, Macomb, MI (US)

(21) Appl. No.: 15/663,387

(22) Filed: Jul. 28, 2017

Related U.S. Application Data
(60) Provisional application No. 62/367,745, filed on Jul. 28, 2016.

(51) Int. Cl. B60L 8/00; B64D 35/02; H01L 31/048; B64C 27/08; B64D 27/24

(52) U.S. Cl. CPC B60L 8/003; B64C 27/08; B64D 27/24; H01L 31/048; B64D 35/02

(57) ABSTRACT

A solar power system for a drone. The system including a shell with at least one solar cell adapted for placement on an exterior surface of a drone. The system coupled to a controller, the controller distributing collected solar energy to the various systems of the drone including the power systems containing batteries and the motor systems adapted to propel the drone.

### CROSS REFERENCE TO RELATED APPLICATIONS

This application claims priority to U.S. Provisional Patent Application No. 62/367,745 filed 28 Jul. 2017 to the above named inventor, and is herein incorporated by reference in its entirety.

### FEDERALLY SPONSORED RESEARCH OR DEVELOPMENT

Not Applicable

### SEQUENCE LISTING, A TABLE, OR A COMPUTER PROGRAM

Not Applicable

### FIELD OF THE INVENTION

The invention relates generally to improvements to a drone to allow for the adaptation of a renewable power source.

### BACKGROUND

Currently there are a number of drones and drone types on the market. A majority of these drones are generally unmanned and adapted for remote control (RC) through a radio transmitter. In general, the battery life of a drone is generally very poor, sometimes as little as a couple of minutes, requiring the batteries powering the drone to be frequently recharged. Still further, some drones offer extended battery life through the use of additional batteries; these additional batteries impact the overall weight of the drone and may impact performance and operation.

Due to the limitations of the batteries of a drone, there is a need in the marketplace for devices that are adapted to increase the power of the drone and to otherwise extend the life of the batteries and the flight time of the drone. Still further, there may be applications, where the power requirements of a given drone are relatively small, and the device may be operated without batteries when adapted with a renewable power source.

### SUMMARY OF THE INVENTION

The included disclosure relates generally to an improved cover assembly adapted for placement on a drone and in coupled communication with the power source and power system of the drone the assembly is placed upon. Generally the cover assembly is impregnated with a plurality of solar cells. Solar cells as disclosed herein are generally an electrical device adapted to convert light energy into electricity. Accordingly, these solar cells may be photovoltaic cells or the like.

These solar cells directly placed within the cover of the drone allow the drone to be powered by or the batteries charged through solar energy. The cells allow for additional flight time by providing a renewable energy source to the drone power system and allow for longer periods of flight time than a conventional RC drone. Accordingly, the solar apparatus of the disclosure can generally be integrated into current lines/devices without changing the specific drone design. In use, the entire top portion of the drone is replaced by an adapted cover assembly comprising a solar cell or series of solar cells arranged within the cover assembly to maximize the surface area of the cover, and wherein a majority of the cover includes solar cells in coupled communication with the power systems of the device.

The cover assembly of the device and including the solar cells can be generally provided in a shell, skin, or body with solar cells encompassing a majority of the cover assembly. The cover assembly of the device allows for easy replacement, and wherein an entire cover assembly device can be replaced if it becomes damaged during operation.

The assembly of the disclosure provides for a longer flight times and provides for a positive impact on the environment by utilizing a renewable energy source.

The assembly of the disclosure including the solar cells of the cover can be provided in alternate couplings wherein the device can be coupled directly to the motor of a drone or coupled to a first battery and a second battery and wherein the collected solar energy can be stored as electricity and provided for later use. Accordingly, the device can be operated in the daylight hours wherein during use the drone is capable of longer flight time by constantly providing electricity to the drone through the solar cells and/or providing a constant charge to the battery.

In an alternate embodiment of the present disclosure, the assembly of the device can be provided in separate and distinct sections and wherein the various sections can be provided in an assembly for replacement. Accordingly the sections are in an electronic coupling and wherein it can be designed in any number of sections, with it anticipated that one, two, three, or four sections may be preferred for ease of use.

The solar adapted cover can improve drone flight by reducing weight, wherein the solar cells allow for a reduction of the battery amount and sizes used within the drone. Accordingly, when adapting the device to smaller drones a complete removal of the battery may be possible.

### BRIEF DESCRIPTION OF THE DRAWINGS

The accompanying drawings are included to provide a further understanding of the present invention and are incorporated in and constitute a part of this specification. The drawings illustrate exemplary embodiments of the present invention and together with the description serve to further explain the principles of the invention. Other aspects of the invention and the advantages of the invention will be better appreciated as they become better understood by reference to the Detailed Description when considered in conjunction with accompanying drawings, and wherein:

FIG. 1 shows a functional block diagram of the systems of the device;

FIG. 2 shows an isometric view of the top of an exemplary drone with the device installed;

FIG. 3 shows the top of an exemplary drone with the device installed;

FIG. 4 shows the front of an exemplary drone with the device installed.

### DETAILED DESCRIPTION OF THE INVENTION

The following detailed description includes references to the accompanying drawings, which form a part of the detailed description. The drawings show, by way of illustration, specific embodiments in which the invention may be practiced. These embodiments, which are also referred to herein as “examples,” are described in enough detail to enable those skilled in the art to practice the invention. The embodiments may be combined, other embodiments may be utilized, or structural, and logical changes may be made without departing from the scope of the present invention. The following detailed description is, therefore, not to be taken in a limiting sense.

Before the present invention is described in such detail, however, it is to be understood that this invention is not limited to particular variations set forth and may, of course, vary. Various changes may be made to the invention described and equivalents may be substituted without departing from the true spirit and scope of the invention. In addition, many modifications may be made to adapt a particular situation, material, composition of matter, process, process act(s) or step(s), to the objective(s), spirit or scope of the present invention. All such modifications are intended to be within the scope of the disclosure made herein.

Unless otherwise indicated, the words and phrases presented in this document have their ordinary meanings to one of skill in the art. Such ordinary meanings can be obtained by reference to their use in the art and by reference to general and scientific dictionaries.

References in the specification to “one embodiment” indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

The following explanations of certain terms are meant to be illustrative rather than exhaustive. These terms have their ordinary meanings given by usage in the art and in addition include the following explanations.

As used herein, the term “and/or” refers to any one of the items, any combination of the items, or all of the items with which this term is associated.

As used herein, the singular forms “a,” “an,” and “the” include plural reference unless the context clearly dictates otherwise.

As used herein, the terms “include,” “for example,” “such as,” and the like are used illustratively and are not intended to limit the present invention.

As used herein, the terms “preferred” and “preferably” refer to embodiments of the invention that may afford certain benefits, under certain circumstances. However, other embodiments may also be preferred, under the same or other circumstances.

Furthermore, the recitation of one or more preferred embodiments does not imply that other embodiments are not useful, and is not intended to exclude other embodiments from the scope of the invention.

As used herein, the term “coupled” means the joining of two members directly or indirectly to one another. Such joining may be stationary in nature or movable in nature and/or such joining may allow for the flow of fluids, electricity, electrical signals, or other types of signals or communication between two members. Such joining may be achieved with the two members or the two members and any additional intermediate members being integrally formed as a single unitary body with one another or with the two members or the two members and any additional intermediate members being attached to one another. Such joining may be permanent in nature or alternatively may be removable or releasable in nature.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element without departing from the teachings of the disclosure.

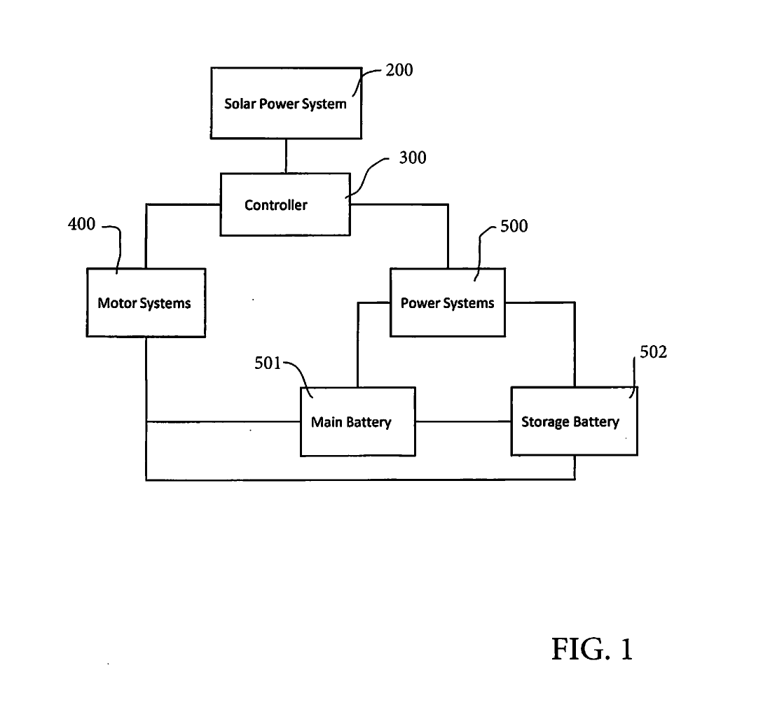

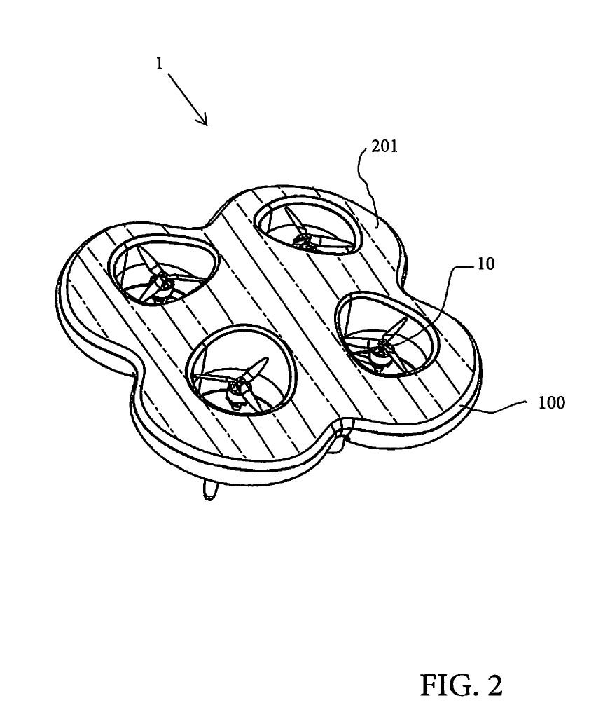

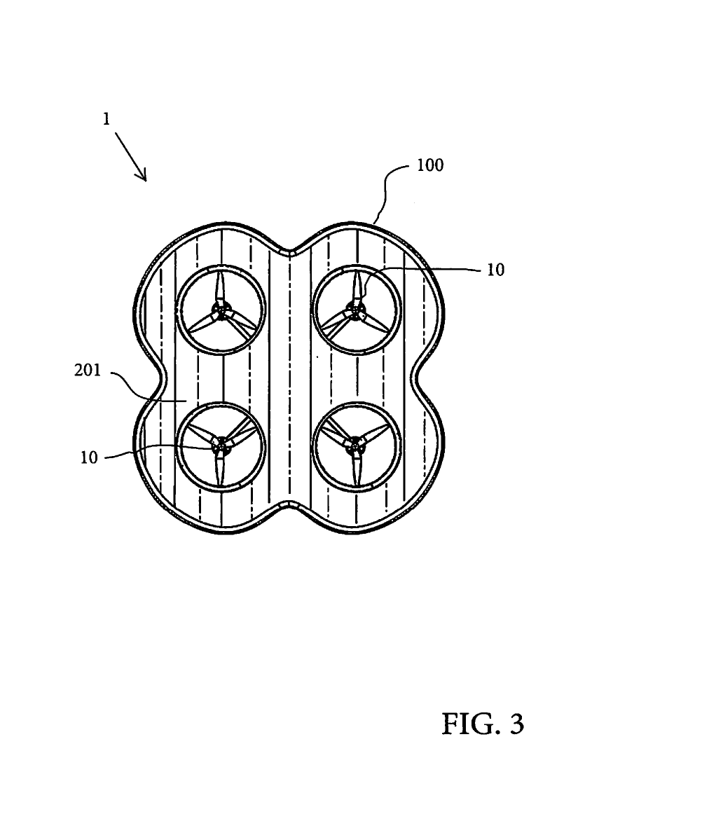

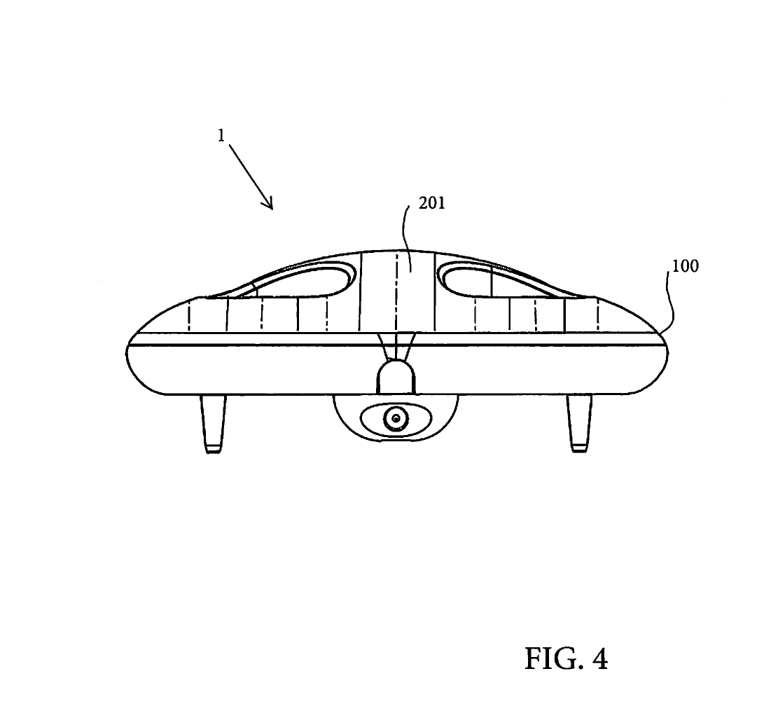

Referring to the figures, FIGS. 1-4 show a drone 1 with solar power system integrated with a power system or motor systems according to the present disclosure. The device of the present disclosure is a removable shell 100 adapted for placement on a drone 1, wherein the shell 100 is provided in a multitude of configurations for affixing to various drone types and styles. Accordingly, the shell 100 can be installed into existing drones 1 as an aftermarket part or integrated into an existing drone 1 during development and manufacturing.

The shell 100 is comprised with at least one solar cell, or photovoltaic cell, generally adapted to convert light energy into electricity. The shell 100 is generally adapted with various couplings in electrical communication with the systems of the device and configured for receipt with the systems of the drone 1.

The shell 100 can be provided in a singular assembly with a single complete shell 100 unit used to collect the solar energy for conversion into electricity for powering the systems of the drone the shell 100 is affixed to. Alternately, the shell 100 can be provided in individual sections and assembled to complete a singular shell 100 unit, wherein the individual sections can be replaced and repaired in the event they become damaged.

Referring now to FIG. 1, the various systems of the device are shown with couplings identified. Accordingly, the shell 100 main component is the solar power system 200 comprised of a variety solar cells 201 adapted to collect light energy for the conversion to electricity for use by the systems of the drone 1 the device is placed upon. The solar cells 201 placed within the shell 100 are preferably photovoltaic cells although other types of solar energy based cells may be utilized.

The solar system 200 is coupled to a controller 300, the controller 300 generally comprised of a processor adapted to communicate and direct the flow of electrical energy produced by the solar system 200 to either the motor systems 400 or power systems 500. The motor systems 400 are generally a propulsion system that generates lift and motion, typically through a propeller 10 or plurality of propellers 10. The motor systems 400 may have additional systems and controls associated with it and wherein the solar power system 200 electricity received can be distributed to various other accessories, such as cameras, directional controllers, or between individual propulsion systems and propellers 10.

The power systems 500 of the device are generally adapted to provide functional power to the device for distribution to the motor systems 400 with either a main battery 501, storage battery 502, or both the main battery 501 and the storage battery 502 providing electrical energy to the motor systems 400 of the device.

Accordingly, the power systems 500 may include both the main battery 501 and the storage battery 502, the main battery 501 only, or the storage battery 502 only. In power systems 500 utilizing both a main battery 501 and a storage battery 502, power from the storage battery 502 can be directed to the main battery 501 for recharging or directed to the motor systems 400 if needed or directed only to the storage battery 502 for later use. In power systems 500 utilizing only a main battery 501 the power system 500 may direct solar power system 200 energy to the main battery 501 for recharging.

The controller 300 is preferably included with the solar power systems 200 of the device and adapted for inclusion within the shell 100. Accordingly, the shell 100, solar systems 200, and controller can be integrated with existing systems of a drone 1, including power systems 500 and motor systems 400.

The shell 100 is designed to be integrated into the drone in a manner that does not otherwise affect the aesthetics or aerodynamics of the drone 1 the shell 100 is placed upon. Accordingly, the shell 100 can be utilized in various configurations and adapted with various features to enhance the flight characteristics of a given drone 1 and wherein the shell 100 may integrated with propulsion of the drone and incorporated in such elements as cowlings, flaps, rudders, or other similar aerodynamic elements and features.

While the invention has been described above in terms of specific embodiments, it is to be understood that the invention is not limited to these disclosed embodiments. Upon reading the teachings of this disclosure many modifications and other embodiments of the invention will come to mind of those skilled in the art to which this invention pertains, and which are intended to be and are covered by both this disclosure and the appended claims. It is indeed intended that the scope of the invention should be determined by proper interpretation and construction of the appended claims and their legal equivalents, as understood by those of skill in the art relying upon the disclosure in this specification and the attached drawings.

What is claimed is:

1. A shell adapted for placement on a drone, the shell comprising:
a solar power system, the solar power system including at least one solar cell, the solar cell capable of converting light energy to electricity;
a controller, the controller in communication with the solar system and capable of distributing electricity to a power source of the drone.

2. A shell as in claim 1, wherein the solar cell is a photovoltaic cell.

3. A shell as in claim 1, wherein the shell is removable.

4. A shell as in claim 1, wherein the shell contains a plurality of solar cells.

5. A shell as in claim 1, wherein the shell is comprised of a single unit.

6. A shell as in claim 1, wherein the shell is comprised of multiple units.

7. An energy system for a drone, the energy system comprising:
a shell, the shell adapted for removable placement on an exterior surface of the drone, the shell including a solar power system, the solar power system including at least one photovoltaic cell capable of generating an electrical current;
a controller, the controller coupled to the solar power system, the controller distributing electrical current to a power system;
the power system including a battery, the battery supplying power to the drone.

8. A system as in claim 7, wherein the controller is coupled to a motor system, the motor system providing propulsive movement of the drone.

9. A system as in claim 7, wherein the power system includes a second battery, the second battery acting a storage battery to store electrical energy.

10. A system as in claim 9, wherein the second battery is in communication with the battery of the power system.

11. A system as in claim 9, wherein the second battery is coupled to the motor system.

12. A system as in claim 7, wherein the shell contains a plurality of photovoltaic cells.

13. A shell as in claim 7, wherein the shell is comprised of a single unit.

14. A shell as in claim 7, wherein the shell is comprised of multiple units.
